(19) United States
(12) Patent Application Publication
(10) Pub. No.: US 2025/0266279 A1
(43) Pub. Date: Aug. 21, 2025

(54) WAFER FRAME POSITIONING STAGE

(71) Applicants: Hsin-Jung PENG, Taoyuan City (TW); Tsung-Che YU, Taoyuan City (TW); SHENG CHUAN TECHNOLOGY CO., LTD., Taoyuan City (TW)

(72) Inventors: Hsin-Jung PENG, Taoyuan City (TW); Tsung-Che YU, Taoyuan City (TW)

(21) Appl. No.: 19/014,290

(22) Filed: Jan. 9, 2025

(30) Foreign Application Priority Data
Feb. 17, 2024 (TW) 113105615

(51) Int. Cl. H01L 21/68; H01L 21/683

(52) U.S. Cl. CPC H01L 21/681; H01L 21/6835

(57) ABSTRACT

A wafer frame positioning stage can hold a wafer frame and has a main body. The main body has a first plane, a first fixed resisting unit, a first movable resisting unit, a driver and an elastic unit. The first plane is horizontally mounted on the main body. The first fixed resisting unit and the first movable resisting unit are respectively located on two opposite ends of the main body and are mounted on the first plane. The driver drives the first movable resisting unit toward or away from the first fixed resisting unit and can clamp the wafer frame. The elastic unit tends to move the first movable resisting unit away from the first fixed resisting unit.

### BACKGROUND OF THE INVENTION

### 1. Field of the Invention

The present invention relates to a wafer frame positioning stage.

### 2. Description of the Prior Arts

When performing wafer cutting, grinding and other processing in the semiconductor industry, a film will be attached to a wafer frame, and then the wafer will be placed on the film of the wafer frame to prevent the wafer from sliding during the processing. After processing, the wafer frame can be cleaned and reused. In other words, during the processing process, the wafer is securely mounted on the wafer frame and moves integrally with the wafer frame.

A wafer frame positioning stage is provided in the processing station of the wafer production line, and is configured to clamp and fix the wafer frame, such that the wafer frame and the wafer can be located in the correct processing position, and prevent the wafer from being displaced during processing. When the wafer and the wafer frame move between the wafer frame positioning stages of the processing station, a robotic arm picks up the wafer frame from one wafer frame positioning stage, and then clamps the wafer frame into another wafer frame positioning stage.

However, components configured to hold the wafer frame of the conventional wafer frame positioning stage are securely mounted on a base, and said components holding the wafer frame cannot move on the base. In other words, the wafer frame positioning stage cannot adjust the clamping strength and range. The wafer frame positioning stage even requires the elastic deformation of the wafer frame to disassemble and install the wafer frame. Therefore, the wafer frame is prone to deform, which affects the processing of the wafer and makes the wafer frame non-reusable.

To overcome the shortcomings, the present invention provides a wafer frame positioning stage to mitigate or obviate the aforementioned problems.

### SUMMARY OF THE INVENTION

The main objective of the present invention is to provide a wafer frame positioning stage that is configured to clamp and fix a wafer frame. The wafer frame positioning stage can prevent the wafer frame from deforming under excessive force during clamping and fixing the wafer frame.

The wafer frame positioning stage has a base and a main body. The main body is securely mounted on the base and configured to hold the wafer frame. The main body has a first plane, a first fixed resisting unit, a first movable resisting unit, a second plane, a second fixed resisting unit, a second movable resisting unit, a driver, and an elastic unit.

The first plane is horizontally formed on the main body. The first fixed resisting unit is securely mounted on the first plane and located on a first end of the main body. The first movable resisting unit is movably mounted on a second end of the main body. The first movable resisting unit and the first fixed resisting unit are located opposite each other.

The second plane is horizontally formed on the main body, and a height of the second plane is higher than a height of the first plane. The second fixed resisting unit is securely mounted on the second plane. The second fixed resisting unit and the first fixed resisting unit are located on the first end of the main body. The second movable resisting unit is movably mounted on the second end of the main body. The second movable resisting unit and the second fixed resisting unit are located opposite each other.

The driver is connected to the first movable resisting unit and drives the first movable resisting unit to move toward or away from the first fixed resisting unit. The elastic unit is connected to the first movable resisting unit and tends to move the first movable resisting unit away from the first fixed resisting unit.

The advantage of the present invention is that the wafer frame positioning stage comprises the elastic unit and the driver. Therefore, when clamping and fixing the wafer frame, the distance and the clamping force between the first fixed resisting unit and the first movable resisting unit can better meet the needs of the wafer frame, and prevent the wafer frame from being deformed. In addition, the wafer frame positioning stage has two clamping positions: the first fixed resisting unit and the first movable resisting unit, and the second fixed resisting unit and the second movable resisting unit. Therefore, the wafer frame positioning stage can hold wafer frames of two different sizes.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a wafer frame positioning stage in accordance with the present invention;

FIG. 2 is a perspective view of the wafer frame positioning stage in FIG. 1, shown with a wafer frame;

FIG. 3 is a perspective view of the wafer frame positioning stage in FIG. 1, shown with another wafer frame;

FIG. 4 is a top view of the wafer frame positioning stage in FIG. 1;

FIG. 5 is a sectional view of the wafer frame positioning stage across line 5-5 in FIG. 4; and

FIG. 6 is an enlarged view of the wafer frame positioning stage in FIG. 4.

### DETAILED DESCRIPTION OF THE PREFERRED EMBODIMENTS

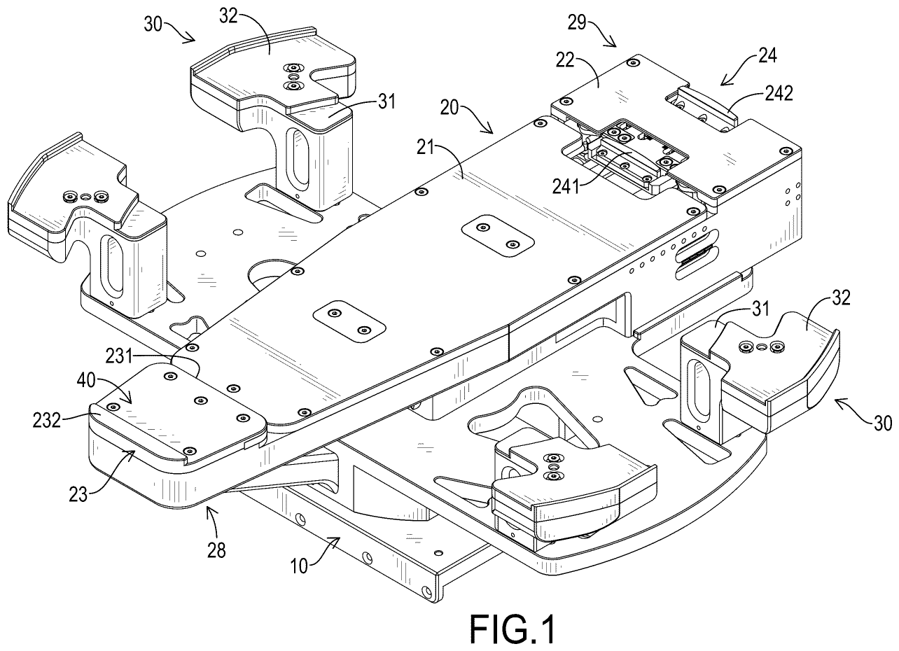

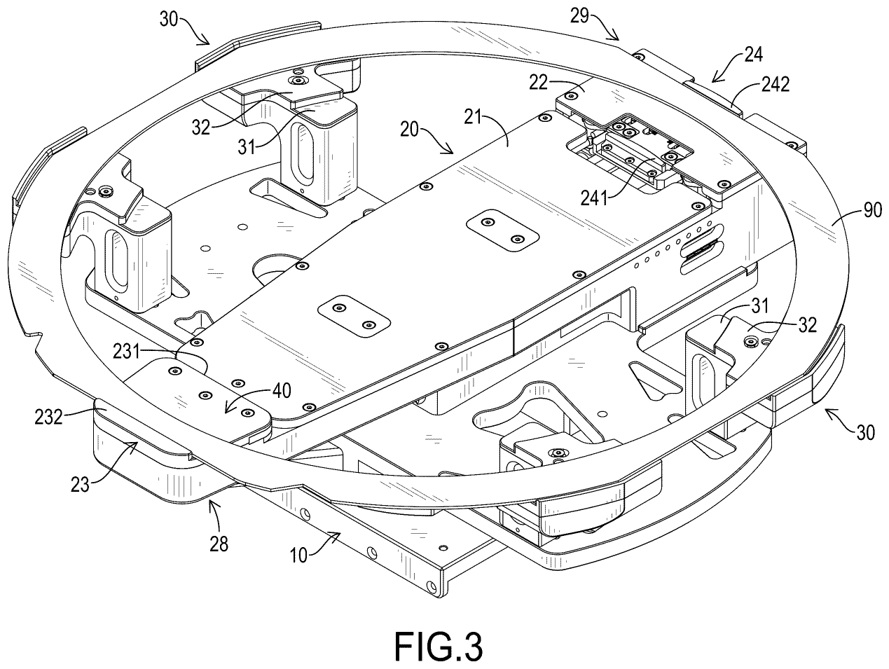

With reference to FIG. 1 to FIG. 3, a wafer frame positioning stage in accordance with the present invention is configured to hold wafer frames 90 of two different sizes. The wafer frame positioning stage comprises a base 10, a main body 20, multiple supporting units 30, and a surface 40. The surface 40 is a part of the wafer frame positioning stage that contacts the wafer frame 90, and the surface 40 comprises an antistatic coating.

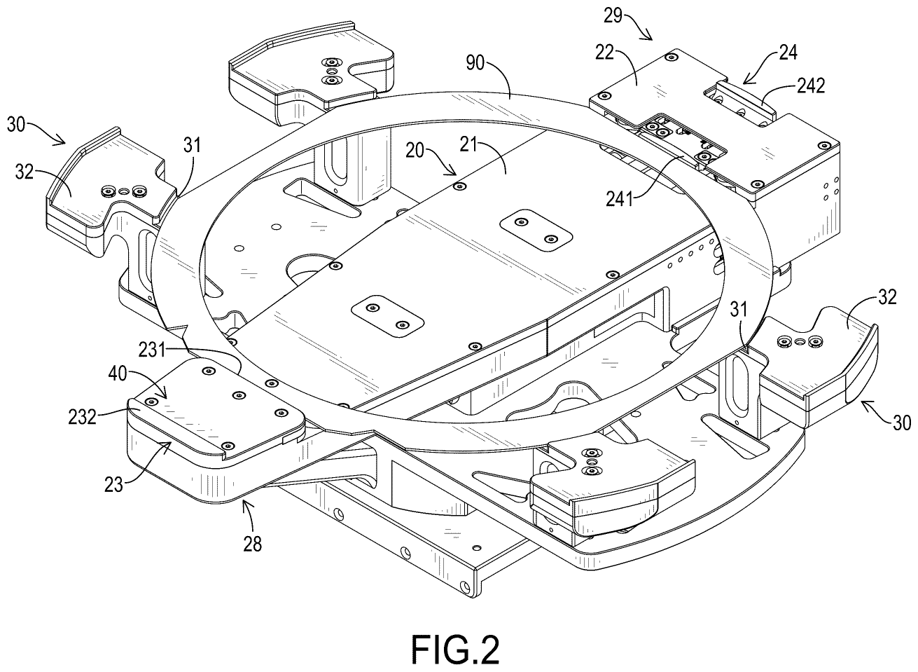

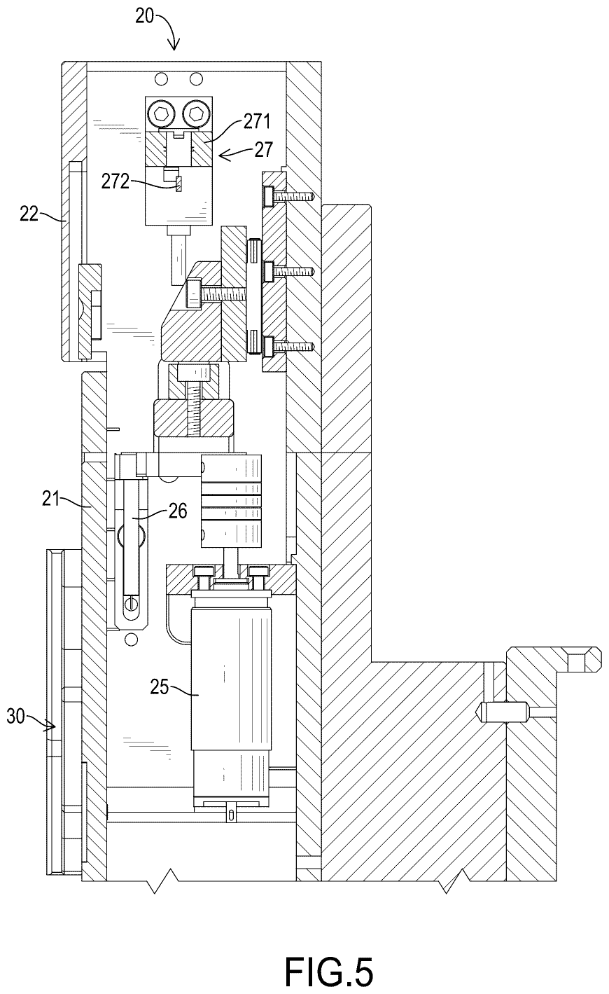

With reference to FIG. 2 to FIG. 6, the base 10 is configured to be securely mounted on a processing station of a production line. The main body 20 is securely mounted on the base 10. The main body 20 comprises a first plane 21, a second plane 22, a fixing assembly 23, a moving assembly 24, a driver 25, an elastic unit 26, and a sensor assembly 27. The first plane 21 and the second plane 22 are horizontally formed on the main body 20, and a height of the second plane 22 is higher than a height of the first plane 21. The wafer frame 90 is placed on the first plane 21 or the second plane 22.

With reference to FIG. 2 to FIG. 4, the fixing assembly 23 can comprise a first fixed resisting unit 231 and a second fixed resisting unit 232, and the moving assembly 24 can comprise a first movable resisting unit 241 and a second movable resisting unit 242. The first fixed resisting unit 231 and the first movable resisting unit 241 are respectively located on two opposite ends of the main body 20 and are mounted on the first plane 21. The first fixed resisting unit 231 is located on a first end 28, and the first movable resisting unit 241 is located on a second end 29. The first movable resisting unit 241 can move toward or away from the first fixed resisting unit 231 on the first plane 21. Therefore, when the first fixed resisting unit 231 and the first movable resisting unit 241 are close to each other, the first fixed resisting unit 231 and the first movable resisting unit 241 can clamp the wafer frame 90 of one size.

Similarly, the second fixed resisting unit 232 and the second movable resisting unit 242 are respectively located on the two opposite ends of the main body 20 and are mounted on the second plane 22. The second fixed resisting unit 232 is located on the first end 28, and the second movable resisting unit 242 is located on the second end 29. The second movable resisting unit 242 can move toward or away from the second fixed resisting unit 232 on the second plane 22. Therefore, when the second fixed resisting unit 232 and the second movable resisting unit 242 are close to each other, the second fixed resisting unit 232 and the second movable resisting unit 242 can clamp the wafer frame 90 of another size. In this embodiment, a distance between the first fixed resisting unit 231 and the first movable resisting unit 241 is smaller than a distance between the second fixed resisting unit 232 and the second movable resisting unit 242.

In this embodiment, the first fixed resisting unit 231 and the second fixed resisting unit 232 are located on the first end 28 of the main body 20, and the first movable resisting unit 241 and the second movable resisting unit 242 are located on the second end 29 of the main body 20. In another embodiment, the first fixed resisting unit 231 and the second movable resisting unit 242 can be located on one of the two ends of the main body 20, and the first movable resisting unit 241 and the second fixed resisting unit 232 can be located on another one of the two ends of the main body 20. Alternatively, a connection line between the first fixed resisting unit 231 and the first movable resisting unit 241 intersects a connection line between the second fixed resisting unit 232 and the second movable resisting unit 242, but it is not limited thereto.

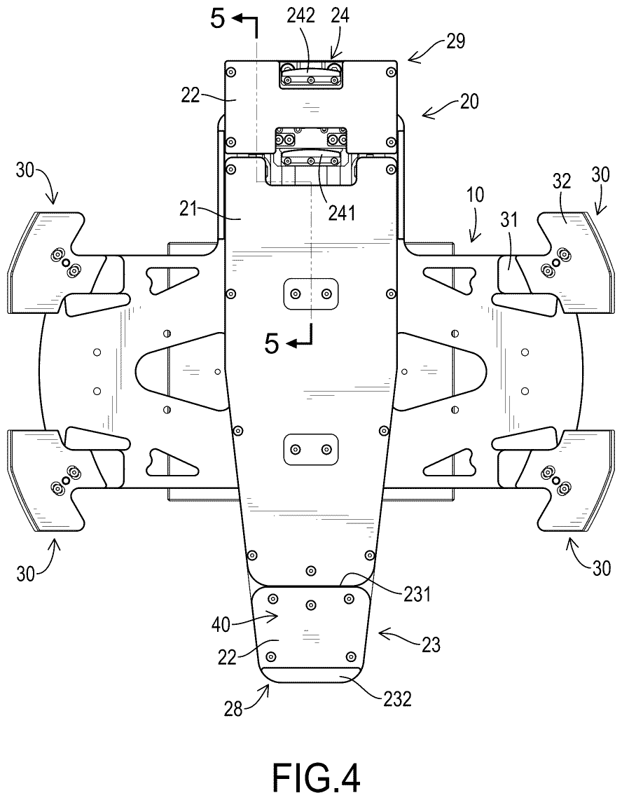

With reference to FIG. 4 to FIG. 6, the driver 25 is connected to the moving assembly 24 and can drive the moving assembly 24 to move toward or away from the fixing assembly 23. In this embodiment, the driver 25 is connected to the first movable resisting unit 241 and the second movable resisting unit 242 at the same time, and drives the first movable resisting unit 241 and the second movable resisting unit 242 to move together. In another embodiment, the main body 20 can comprise two drivers 25, one of the drivers 25 is connected to the first movable resisting unit 241, another one of the drivers 25 is connected to the second movable resisting unit 242, but it is not limited thereto.

The elastic unit 26 is connected to the moving assembly 24 and tends to move the moving assembly 24 away from the fixing assembly 23. In other words, when the first fixed resisting unit 231 and the first movable resisting unit 241 clamp the wafer frame 90, the elastic unit 26 can help the wafer frame 90 resist a clamping force between the first fixed resisting unit 231 and the first movable resisting unit 241. Similarly, when the second fixed resisting unit 232 and the second movable resisting unit 242 clamp the wafer frame 90, the elastic unit 26 can help the wafer frame 90 resist a clamping force between the second fixed resisting unit 232 and the second movable resisting unit 242. Therefore, this can prevent the wafer frame 90 from being deformed under excessive extrusion.

The sensor assembly 27 is signally connected to the driver 25. The sensor assembly 27 is configured to detect a position of the moving assembly 24, such that the driver 25 can drive the moving assembly 24. In this embodiment, the main body 20 comprises two sensor assemblies 27, which are the first sensor assembly 27A and the second sensor assembly 27B. The two sensor assemblies 27 are optical sensors and are respectively mounted on two sides of the moving assembly 24. Each one of the sensor assemblies 27 comprises a first part 271 and a second part 272. The first part 271 can emit and sense an optical signal. The second part 272 is securely mounted on the moving assembly 24, and the second part 272 can move with the moving assembly 24 and selectively block the optical signal emitted by the first part 271.

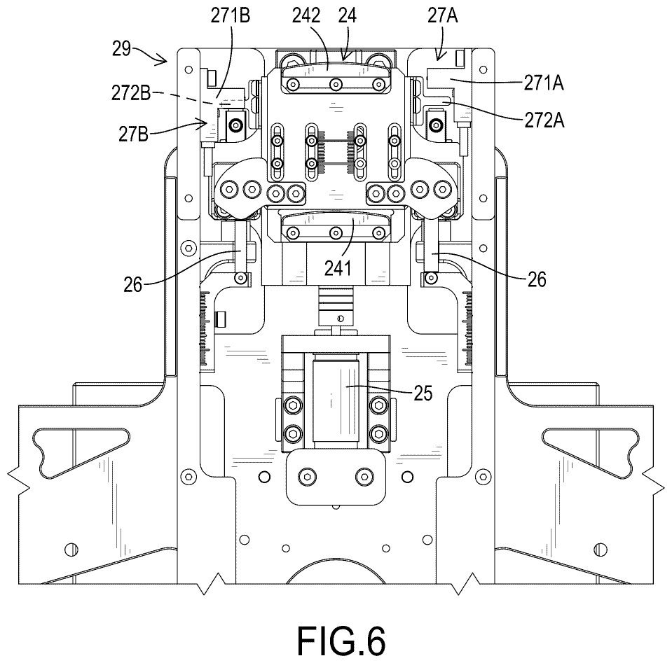

When the moving assembly 24 moves away from the fixing assembly 23, the second part 272A of the first sensor assembly 27A blocks the optical signal emitted by the first part 271A, and the second part 272B of the second sensor assembly 27B does not block the optical signal emitted by the first part 271B. As shown in FIG. 6, when the moving assembly 24 moves toward the fixing assembly 23, the second part 272A of the first sensor assembly 27A does not block the optical signal emitted by the first part 271A, and the second part 272B of the second sensor assembly 27B blocks the optical signal emitted by the first part 271B. The position of the moving assembly 24 can be determined by whether the optical signal of each one of the sensor assemblies 27 is blocked.

With reference to FIG. 2 to FIG. 4, the supporting units 30 are securely mounted on the base 10 and are separately mounted on two sides of the main body 20. A top of each one of the supporting units 30 comprises a first surface 31 and a second surface 32. The first surface 31 and the second surface 32 are two horizontal surfaces. A height of the first surface 31 is same to the height of the first plane 21, and a height of the second surface 32 is same to the height of the second plane 22. The wafer frame 90 of one size can be placed on the first plane 21 and the first surface 31, and the wafer frame 90 of another size can be placed on the second plane 22 and the second surface 32. However, only one wafer frame 90 can be placed on the wafer frame positioning stage at a given time. In this embodiment, the wafer frame positioning stage comprises four supporting units 30. Two of the four supporting units 30 are located on one side of the main body 20, and the other two of the four supporting units 30 are located on another side of the main body 20. In another embodiment, an amount of the supporting units 30 is not limited thereto, as long as the supporting units 30 can stably hold the wafer frame 90.

Before the wafer frame 90 is placed on the wafer frame positioning stage, the driver 25 drives the moving assembly 24 to move away from the fixing assembly 23, until the second part 272A of the first sensor assembly 27A blocks the optical signal emitted by the first part 271A, and the second part 272B of the second sensor assembly 27B does not block the optical signal emitted by the first part 271B. When the wafer frame 90 is placed on the wafer frame positioning stage, the driver 25 drives the moving assembly 24 to move toward the fixing assembly 23, until the second part 272A of the first sensor assembly 27A does not block the optical signal emitted by the first part 271A, and the second part 272B of the second sensor assembly 27B blocks the optical signal emitted by the first part 271B. Therefore, the moving assembly 24 and the fixing assembly 23 can clamp the wafer frame 90. At this time, if the size of the wafer frame 90 s slightly larger than a distance between the moving assembly 24 and the fixing assembly 23, the elastic unit 26 can help the wafer frame 90 resist the clamping force of the moving assembly 24 and the fixing assembly 23.

The advantage of the present invention is that the wafer frame positioning stage comprises the elastic unit 26 and the driver 25. Therefore, when clamping and fixing the wafer frame 90, the distance and the clamping force between the first fixed resisting unit 231 and the first movable resisting unit 241 can better meet the needs of the wafer frame 90, and prevent the wafer frame 90 from being deformed. In addition, the wafer frame positioning stage has two clamping positions: the first fixed resisting unit 231 and the first movable resisting unit 241, and the second fixed resisting unit 232 and the second movable resisting unit 242. Therefore, the wafer frame positioning stage can hold the wafer frames 90 of two different sizes.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A wafer frame positioning stage configured to hold a wafer frame; the wafer frame positioning stage comprising:
a base;
a main body securely mounted on the base and configured to hold the wafer frame; the main body comprising:
a first plane horizontally formed on the main body;
a first fixed resisting unit securely mounted on the first plane and located on a first end of the main body;
a first movable resisting unit movably mounted on a second end of the main body; the first movable resisting unit and the first fixed resisting unit located opposite each other;
a second plane horizontally formed on the main body; a height of the second plane being higher than a height of the first plane;
a second fixed resisting unit securely mounted on the second plane and located on the first end of the main body;
a second movable resisting unit movably mounted on the second end of the main body; the second movable resisting unit and the second fixed resisting unit located opposite each other;
a driver connected to the first movable resisting unit and driving the first movable resisting unit to move toward or away from the first fixed resisting unit;
an elastic unit connected to the first movable resisting unit and tending to move the first movable resisting unit away from the first fixed resisting unit.

2. The wafer frame positioning stage as claimed in claim 1, wherein the wafer frame positioning stage comprises multiple supporting units; the supporting units are securely mounted on the base and separately mounted on two sides of the main body; a height of a top of each one of the supporting units is same to the height of the first plane.

3. The wafer frame positioning stage as claimed in claim 1, wherein the wafer frame positioning stage comprises:
multiple supporting units securely mounted on the base; the supporting units separately mounted on two sides of the main body; a top of each one of the supporting units comprising:
a first surface; a height of the first surface being same to the height of the first plane;
a second surface; a height of the second surface being same to the height of the second plane.

4. The wafer frame positioning stage as claimed in claim 1, wherein the wafer frame positioning stage comprises a sensor assembly; the sensor assembly is configured to detect a position of the first movable resisting unit, such that the driver is capable of driving the first movable resisting unit according to the position of the first movable resisting unit.

5. The wafer frame positioning stage as claimed in claim 2, wherein the wafer frame positioning stage comprises a sensor assembly; the sensor assembly is configured to detect a position of the first movable resisting unit, such that the driver is capable of driving the first movable resisting unit according to the position of the first movable resisting unit.

6. The wafer frame positioning stage as claimed in claim 3, wherein the wafer frame positioning stage comprises a sensor assembly; the sensor assembly is configured to detect a position of the first movable resisting unit, such that the driver is capable of driving the first movable resisting unit.

7. The wafer frame positioning stage as claimed in claim 4, wherein the sensor assembly is an optical sensor.

8. The wafer frame positioning stage as claimed in claim 5, wherein the sensor assembly is an optical sensor.

9. The wafer frame positioning stage as claimed in claim 6, wherein the sensor assembly is an optical sensor.

10. The wafer frame positioning stage as claimed in claim 1, wherein the wafer frame positioning stage comprises a surface; the surface is configured to contact the wafer frame, and the surface comprises an antistatic coating.

11. The wafer frame positioning stage as claimed in claim 8, wherein the wafer frame positioning stage comprises a surface; the surface is configured to contact the wafer frame, and the surface comprises an antistatic coating.

12. The wafer frame positioning stage as claimed in claim 9, wherein the wafer frame positioning stage comprises a surface; the surface is configured to contact the wafer frame, and the surface comprises an antistatic coating.
